(19) United States
(12) Patent Application Publication
(10) Pub. No.: US 2025/0012737 A1
(43) Pub. Date: Jan. 9, 2025

(54) OPTICAL METROLOGY WITH INFLUENCE MAP OF UNKNOWN SECTION

(71) Applicant: Onto Innovation Inc., Wilmington, MA (US)

(72) Inventors: Yiliang LIU, Singapore (SG); Yong LI, Singapore (SG); Yang WANG, Singapore (SG); Jingsheng SHI, Singapore (SG)

(73) Assignee: Onto Innovation Inc., Wilmington, MA (US)

(21) Appl. No.: 18/705,115

(22) PCT Filed: Nov. 22, 2022
(86) PCT No.: PCT/US2022/050790

§ 371 Date: Apr. 26, 2024

Related U.S. Application Data
(60) Provisional application No. 63/283,201, filed on Nov. 24, 2021.

(51) Int. Cl. G01N 21/956; G01B 11/06; G01N 21/17; G01N 21/21; G01N 21/95; G06T 7/62; H01L 21/66

(52) U.S. Cl. CPC G01N 21/95607; G01B 11/0625; G01N 21/9501; G06T 7/62; H01L 22/12; G01B 2210/56; G01N 2021/1738; G01N 2021/213

(57) ABSTRACT

Optical measurement of a sample that includes a structure-of-interest (SOI) optically coupled to a section having an unknown structure is optically measured using an influence map of the deviation contribution from the unknown structure. The influence map is generated by obtaining metrology data for a plurality of locations that include the SOI and unknown structure and determining the deviation contribution at each location by decoupling the deviation contribution from base contributions from the SOI and unknown structure. During measurement of a location, the deviation contribution associated with that location may be obtained from the influence map and removed from the measured data. The processed data may be fit with a model that includes a rigorous model for the SOI and an effective model for the base contribution of the unknown structure to determine one or more parameters of the SOI.

### CROSS REFERENCE TO RELATED APPLICATIONS

This application claims priority under 35 USC 119 to U.S. Provisional Application No. 63/283,201, entitled “OPTICAL METROLOGY WITH INFLUENCE MAP OF UNKNOWN SECTION,” filed Nov. 24, 2021, which is incorporated herein by reference in its entirety.

### FIELD OF THE DISCLOSURE

The subject matter described herein are related generally to optical metrology, and more particularly to modeling and measuring structures that include unknown sections.

### BACKGROUND

Semiconductor and other similar industries often use optical metrology equipment to provide non-contact evaluation of samples during processing. With optical metrology, a sample under test is illuminated with light, e.g., at a single wavelength or multiple wavelengths. After interacting with the sample, the resulting light is detected and analyzed to determine one or more characteristics of the sample.

The analysis typically includes a model of the structure under test. The model may be generated based on the materials and the nominal parameters of the structure, e.g., film thicknesses, line and space widths, etc. One or more parameters of the model may be varied and the predicted data may be calculated for each parameter variation based on the model, e.g., using Rigorous Coupled Wave Analysis (RCWA) or other similar techniques. The measured data may be compared to the predicted data for each parameter variation, e.g., in a nonlinear regression process, until a good fit is achieved between the predicted data and the measured data, at which time the fitted parameters are determined to be an accurate representation of the parameters of the structure under test.

Modeling techniques are particularly useful when the sample has periodic structure. Unfortunately, when the sample includes sections that are non-periodic, analytically modeling the sample can be difficult. Moreover, if the sample includes one or more sections with unknown design and/or characteristics, i.e., preliminary structural information for one or more sections is unknown or unavailable, building a rigorous model for the sample is not possible. Therefore, an improved optical metrology process that can be used to measure sample structures that include unknown and/or non-periodic sections is desirable.

### SUMMARY

Optical measurement of a sample that includes a structure-of-interest (SOI) optically coupled to a section having an unknown structure is optically measured using an influence map of the deviation contribution from the unknown structure. The influence map is generated by obtaining metrology data from a plurality of locations that include the SOI and unknown structure and determining the deviation contribution at each location by decoupling the deviation contribution from base contributions from the SOI and unknown structure. During measurement of a location, the deviation contribution associated with that location may be retrieved from the influence map and removed from the measured data. The processed data may be fit with a model that includes a rigorous model for the SOI and an effective model for the base contribution of the unknown structure to determine one or more parameters of the SOI.

In one implementation, a method of producing an influence map for optical measurement of a sample, includes obtaining metrology data from a plurality of locations, wherein the metrology data obtained from each location is a combination of a first base contribution from a structure-of-interest (SOI) having known structure, a second base contribution from a section having unknown structure, and a deviation contribution from the section having unknown structure. The method includes determining for each location the deviation contribution from the section having unknown structure based on the metrology data from the plurality of locations. The method further includes storing the deviation contribution and associated location for each location of the plurality of locations to generate the influence map of the section having unknown structure.

In one implementation, a system for producing an influence map for optical measurement of a sample includes means for obtaining metrology data from a plurality of locations, wherein the metrology data obtained from each location is a combination of a first base contribution from a structure-of-interest (SOI) having known structure, a second base contribution from a section having unknown structure, and a deviation contribution from the section having unknown structure. The system may further include means for determining for each location the deviation contribution from the section having unknown structure based on the metrology data from the plurality of locations. The system may further include means for storing in the memory the deviation contribution and associated location for each location of the plurality of locations to generate the influence map of the section having unknown structure.

In one implementation, a system for producing an influence map for optical measurement of a sample, includes one or more processors and a memory coupled to the one or more processors and storing instructions that, when executed by the one or more processors, cause the system to perform operations. The system for example is configured to obtain metrology data from a plurality of locations, wherein the metrology data obtained from each location is a combination of a first base contribution from a structure-of-interest (SOI) having known structure, a second base contribution from a section having unknown structure, and a deviation contribution from the section having unknown structure. The system is further configured to determine for each location the deviation contribution from the section having unknown structure based on the metrology data from the plurality of locations. The system is further configured to store in the memory the deviation contribution and associated location for each location of the plurality of locations to generate the influence map of the section having unknown structure.

In one implementation, a method of producing a model for optical measurement of a structure-of-interest (SOI) on a sample, includes obtaining metrology data from different locations on a sample, wherein each of the different locations on the sample comprises the SOI having known structure and a section having unknown structure that varies over different locations, wherein metrology data obtained from each of the different locations comprise a first base contribution from the SOI having known structure, a second base contribution from the section having unknown structure, and a deviation contribution from the section having unknown structure, wherein the deviation contribution from the section having unknown structure varies for each of the different locations. The method includes obtaining an influence map for the sample comprising deviation contributions associated with each of the different locations. The method further includes generating a model for optical measurement of the SOI using the metrology data obtained from the different locations and the influence map, the model comprising a rigorous model that represents the SOI and an effective model that represents the second base contribution from the section having unknown structure without the deviation contribution.

In one implementation, a system for producing a model for optical measurement of a structure-of-interest (SOI) on a sample includes means for obtaining metrology data from different locations on the sample, wherein each of the different locations on the sample comprises the SOI having known structure and a section having unknown structure that varies over the different locations, wherein metrology data obtained from each of the different locations comprise a first base contribution from the SOI having the known structure, a second base contribution from the section having unknown structure, and a deviation contribution from the section having unknown structure, wherein the deviation contribution from the section having unknown structure varies for each of the different locations. The system may further include means for obtaining an influence map for the sample comprising deviation contributions associated with each of the different locations. The system may further include means for generating the model for optical measurement of the SOI using the metrology data obtained from the different locations and the influence map, the model comprising a rigorous model that represents the SOI and an effective model that represents the second base contribution from the section having unknown structure without the deviation contribution.

In one implementation, a system for producing a model for optical measurement of a structure-of-interest (SOI) on a sample includes one or more processors and a memory coupled to the one or more processors and storing instructions that, when executed by the one or more processors, cause the system to perform operations. The system, for example, is configured to obtain metrology data from different locations on a sample, wherein each of the different locations on the sample comprises the SOI having known structure and a section having unknown structure that varies over different locations, wherein metrology data obtained from each of the different locations comprise a first base contribution from the SOI having known structure, a second base contribution from the section having unknown structure, and a deviation contribution from the section having unknown structure, wherein the deviation contribution from the section having unknown structure varies for each of the different locations. The system is further configured to obtain an influence map for the sample comprising deviation contributions associated with each of the different locations. The system is further configured to generate a model for optical measurement of the SOI using the metrology data obtained from the different locations and the influence map, the model comprising a rigorous model that represents the SOI and an effective model that represents the second base contribution from the section having unknown structure without the deviation contribution.

In one implementation, a method of optical measurement of a sample includes obtaining metrology data from a location on the sample, wherein the metrology data is a combination of a first base contribution from a structure-of-interest (SOI) having known parameters, a second base contribution from a section having unknown structure, and a deviation contribution from the section having unknown structure. The method includes obtaining an influence map for the sample comprising the deviation contribution associated with a plurality of locations on the sample. The method further includes removing from the metrology data obtained from the location the deviation contribution associated with the location to generate processed metrology data comprising the combination of the first base contribution from the SOI and the second base contribution from the section having unknown structure without the deviation contribution, and determining one or more parameters of the SOI using the processed metrology data and a model for optical measurement of the SOI comprising a rigorous model that represents the SOI and an effective model that represents the second base contribution from the section having unknown structure without the deviation contribution.

In one implementation, a metrology device configured for optical measurement of a sample includes a light source that produces light to be incident on the sample and a detector that detects the light from the sample. The metrology device further includes means for obtaining metrology data from a location on the sample, wherein the metrology data is a combination of a first base contribution from a structure-of-interest (SOI) having known parameters, a second base contribution from a section having unknown structure, and a deviation contribution from the section having unknown structure. The metrology device further includes means for obtaining an influence map for the sample comprising the deviation contribution associated with a plurality of locations on the sample. The metrology device further includes means for removing from the metrology data obtained from the location the deviation contribution associated with the location to generate processed metrology data comprising the combination of the first base contribution from the SOI and the second base contribution from the section having unknown structure without the deviation contribution. The metrology device further includes means for determining one or more parameters of the SOI using the processed metrology data and a model for optical measurement of the SOI comprising a rigorous model that represents the SOI and an effective model that represents the second base contribution from the section having unknown structure without the deviation contribution.

In one implementation, a metrology device configured for optical measurement of a sample including a light source that produces light to be incident on the sample, a detector that detects the light from the sample, one or more processors coupled to the detector, and a memory coupled to the one or more processors and storing instructions that, when executed by the one or more processors, cause the metrology device to perform operations. The metrology device, for example, is configured to obtain metrology data from a location on the sample, wherein the metrology data is a combination of a first base contribution from a structure-of-interest (SOI) having known parameters, a second base contribution from a section having unknown structure, and a deviation contribution from the section having unknown structure. The metrology device is further configured to obtain an influence map for the sample comprising the deviation contribution associated with a plurality of locations on the sample. The metrology device is further configured to remove from the metrology data obtained from the location the deviation contribution associated with the location to generate processed metrology data comprising the combination of the first base contribution from the SOI and the second base contribution from the section having unknown structure without the deviation contribution. The metrology device is further configured to determine one or more parameters of the SOI using the processed metrology data and a model for optical measurement of the SOI comprising a rigorous model that represents the SOI and an effective model that represents the second base contribution from the section having unknown structure without the deviation contribution.

### BRIEF DESCRIPTION OF THE DRAWINGS

FIG. 1 illustrates a side view of one example of a region-of-interest (ROI) of a sample that includes an SOI that has a known structure with little or no variation across the ROI and a section having an unknown structure that varies across the ROI.

FIG. 2 illustrates a top plan view of a wafer that includes a die that includes the ROI.

FIG. 3 is a graph illustrating examples of the data that may be collected from a plurality of locations on the ROI within the die shown in FIG. 2.

FIG. 4 illustrates a side view of an example of a region-of-interest (ROI) of a sample that is on wafer level and that includes an SOI having a known structure and a section having an unknown structure, both the SOI and the unknown structure may vary across the wafer.

FIG. 5 illustrates a top plan view of a wafer that includes a plurality of dies corresponding to the ROI shown in FIG. 4.

FIG. 6 illustrates a schematic view of an optical metrology device that may be used to generate and use an influence map of an unknown section of a sample for measuring one or more parameters of a SOI.

FIG. 7 illustrates a process of measuring a sample that includes a SOI with a known structure and a section having an unknown structure, including generating and using an influence map and building and using an effective model for the unknown structure.

FIG. 8 illustrates a reference region of a sample that includes a SOI and an unknown structure.

FIG. 9 illustrates a plurality of locations in the ROI from which measurement data are collected and graphs illustrating an example of the measurement data that are collected from a plurality of locations and decoupling the deviation contribution from the measurement data for each location.

FIG. 10A graphically illustrates an influence map for the deviation contribution associated with each location in a reference region.

FIG. 10B graphically illustrates an influence map for the deviation contribution associated with each location in a reference region generated by stitching together multiple influence maps from multiple locations within the reference region.

FIG. 11 illustrates an example of a model of the sample that includes a rigorous model for the SOI and an effective model for the base contribution component from the unknown structure.

FIG. 12 illustrates the measurement data collected from a measurement site on a sample under test and the processed data after removing the deviation contribution of the unknown structure from the measurement site.

FIG. 13 illustrates a graph including an example of fitting the modeled data to the processed data.

FIG. 14 is a flow chart illustrating a method of producing an influence map of the unknown structure for optical measurement of a sample.

FIG. 15 is a flow chart illustrating a method of producing a model for optical measurement of a structure-of-interest (SOI) on a sample.

FIG. 16 is a flow chart illustrating a method for optical measurement of a sample.

### DETAILED DESCRIPTION

During fabrication of semiconductor and similar devices it is sometimes necessary to monitor the fabrication process by non-destructively measuring the devices. Optical metrology may be employed for non-contact evaluation of samples during processing. Optical metrology techniques, such as thin film metrology and Optical Critical Dimension (OCD) metrology, may use modeling of the structure to generate predicted data that is be compared with the measured data from the sample. Variable parameters in the model, such as layer thicknesses, line widths, space widths, sidewall angles, etc., may be varied and the predicted data is generated for each variation. The measured data may be compared with the predicted data for each parameter variation, e.g., in a nonlinear regression process, until a good fit is achieved, at which time the values of the fitted parameters are determined to be an accurate representation of the parameters of the sample.

Conventionally, modeling requires that preliminary structural and material information is known about the sample in order to generate an accurate representative model of the sample, which may include one or more variable parameters. For example, the preliminary structural and material information for a sample may include a physical description of the sample with nominal values for various parameters, such as layer thicknesses, line widths, space widths, sidewall angles, etc., along with a range within which these parameters may vary. The sample may further include one or parameters that are not variable, i.e., are not expected to change in a significant amount during manufacturing. If the structure and/or materials of the SOI is unknown, i.e., the preliminary structural and material information is unknown or unavailable, an accurate model cannot be generated.

Additionally, modeling using techniques such as Rigorous Coupled Wave Analysis (RCWA) requires that the modeled structure is periodic. The use of RCWA in a modeling engine is desirable because it is fast and efficient, with the requirement that the structure is periodic. Accordingly, modeling techniques that require periodicity, such as RCWA, are conventionally unsuitable for non-periodic structures. Other modeling techniques that do not require periodicity, such as Finite-Difference Time-Domain (FDTD) or Finite Element Method (FEM), may be used with aperiodic structures, but these techniques require rigorous modeling of the entire structure, as well as nanometer-level positioning during measurement to ensure that the measured area matches the modeled area.

Accordingly, if structural (or material) information for one or more sections of a sample are unknown and/or if the structure is non-periodic, optical metrology using modeling may not be possible. By way of example, a sample may include a structure-of-interest (SOI), which can be modeled, that is optically coupled to a section of the sample with an unknown structure, e.g., preliminary structural and material information is unknown or unavailable, which may sometimes be referred to herein as the “unknown structure.” The unknown structure, additionally, may be non-periodic or may be periodic. The SOI, for example, may be on the upper layer(s) of the sample, while the unknown structure may be on lower layer(s) which underlie the SOI. In other examples, the unknown structure may be above the SOI or to the side of the SOI, or may be combined with the SOI, e.g., on the same layer and intermixed with the SOI. During optical measurement of the sample, light that is returned from the unknown structure may be coupled to light that is returned from the SOI in a complicated manner that may be difficult to decouple. Moreover, the unknown structure cannot be rigorously modeled due, e.g., to its unknown structure and possibly its non-periodicity, and accordingly, a rigorous model for the combined SOI and unknown structure cannot be built. Consequently, conventional optical metrology techniques for such a sample is challenging because the predicted data for the sample cannot be generated from a rigorous model to fit to the measured data.

As discussed herein, optical metrology of a sample that includes a SOI and an unknown section may be performed by minimizing the undesired/unknown influence on the measured data that is due to the unknown section. An influence map of the deviation contribution associated with each location from a plurality of locations on a region-of-interest (ROI) may be generated using various processing techniques. The unknown section's deviation contribution associated with a measurement site may then be removed from the measured data. With the deviation contribution removed, the processed data will be more dominated by the SOI, which may be modeled. Any remaining unvarying contribution from the unknown section may be modeled using an effective model, which may be combined with the rigorous model of the SOI.

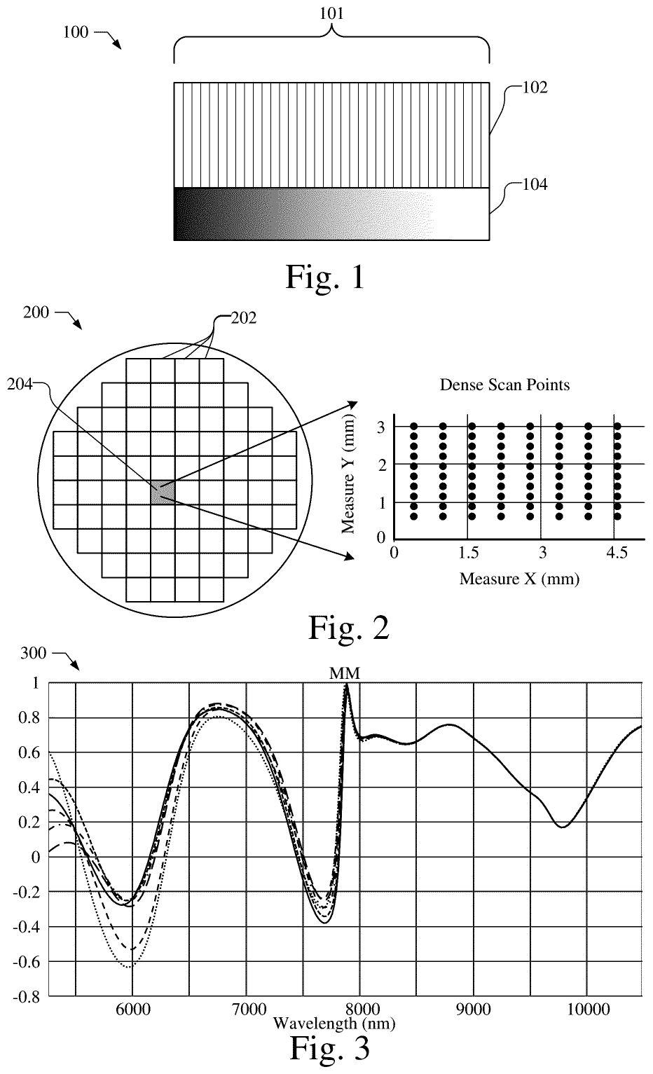

FIG. 1 illustrates a side view of one example of a region-of-interest (ROI) 101 of a sample 100 that includes an SOI 102 that has a known structure and a section 104 having an unknown structure, sometimes referred to as unknown structure 104. FIG. 1 illustrates the SOI 102 as overlying the unknown structure 104, but in some implementations, the unknown structure 104 may overlie the SOI 102 or may be to the side of the SOI 102 (e.g., on the same layer(s)) or may be combined or intermixed with the SOI 102.

The SOI 102 has a known structure, i.e., preliminary structural and material information for the SOI 102 is available. Accordingly, the SOI 102 may be rigorously modeled using RCWA (for a periodic structure) or using FDTD or FEM (for a non-periodic structure). The unknown structure 104, on the other hand, has an unknown structure, i.e., preliminary structural and material information is unknown or unavailable. The unknown structure 104 may be non-periodic over the ROI 101. Moreover, as illustrated with the variation in shading of the unknown structure 104, the unknown structure 104 may vary within the ROI 101. Consequently, as discussed above, rigorous modeling of the unknown structure 104 is not possible.

By way of example, in some implementations, the unknown structure 104 may be a circuit, such as a complementary metal-oxide-semiconductor (CMOS) circuit, or some other underlaying (overlying) circuit, and the SOI 102 may be a repetitive structures such as Vertical NAND (V-NAND) or Dynamic Random-Access Memory (DRAM) structures. The unknown structure 104, alternatively, may be structures containing complex regions that were produced in earlier fabrication process steps, while the SOI 102 is in current fabrication process step. In some implementations, the unknown structure 104 may be periodic and may have the same (or different) periodicity as the SOI 102, but the unknown structure 104 may have a different sensitivity to optical metrology than the SOI 102, e.g., different sensitive wavelength regions, different spectral sensitivity signatures, etc.

The unknown structure 104 may vary within the ROI 101, but may be repeatable across corresponding ROIs on the sample. For example, the variation of the unknown structure 104 across different ROIs may be much smaller than the variation within a single ROI 101. As a result, the influence mapping of the unknown structure 104 will be repeatable from ROI to ROI, so that a map extracted from one ROI can be applied to other ROIs and wafers. The variation in the SOI 102 across the ROI 101, on the other hand, is small, i.e., the SOI 102 is consistent within the ROI 101 due to small in-ROI process variation.

FIG. 2, by way of example, illustrates a top plan view of a wafer 200 that includes a plurality of dies 202. The ROI 101 illustrated in FIG. 1 may be on the die level, as illustrated by the shaded die 204 on the wafer 200. In some implementations, the ROI 101 is a region within the die.

The data collected from a plurality of locations on the same die 204 (or ROI 101 shown in FIG. 1) may vary considerably due to the influence of the unknown structure 104, which varies over the ROI. FIG. 2, by way of example, illustrates measurements may be collected over a dense scan of points on the die 204 (or ROI 101) to collect data from a plurality of locations.

FIG. 3, by way of example, is a graph 300 illustrating examples of the data that may be collected from a plurality of locations on the die 204 (or ROI 101) shown in FIG. 2. The data in graph 300, for example, illustrates spectral data for a Mueller matrix (MM) element between approximately 5,300 nm and 10,500 nm. Each curve illustrated in FIG. 3 represents the MM spectral data for one location within die 204 (or ROI 101). As can be seen, on the same die 204 (or ROI 101), the collected spectra show a large variation from location to location, particularly in the shorter wavelength range, e.g., between 5,300 nm and 7,800 nm. As discussed above, there is little or no variation in the SOI 102 across the ROI 101, while the unknown structure 104 varies across the ROI 101, and accordingly, variation in the collected data from location to location within the ROI 101 is primarily due to the variation in the unknown structure 104 within the ROI 101. While a single MM element is illustrated in FIG. 3, it should be understood that other MM elements and other types of metrology data, such as ellipsometric data including Psi & Delta data, Jones matrix, etc., reflectometric data including reflectance collected at different polarizer angles and/or different angles of incidence (AOIs), interferometric data including spectra in frequency domain, Fourier-Transform Infrared Spectroscopy (FTIR) data, etc., may have a similarly large variation over the ROI 101.

In some implementations, the ROI may be on the wafer level that consists of a single or multiple measurement sites from a plurality of dies over the wafer.

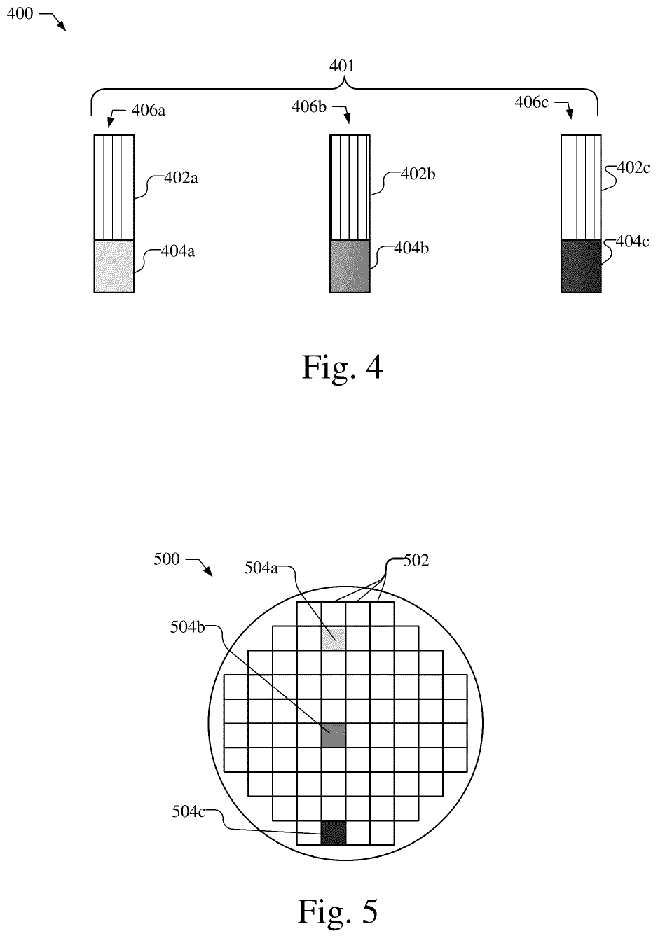

FIG. 4, for example, illustrate a side view of an example of a ROI 401 of a sample 400 that is on the wafer level and includes a SOI 402a, 402b, and 402c (sometimes collectively referred to as SOI 402) and an unknown structure 404a, 404b, and 404c (sometimes collectively referred to as unknown structure 404). Rather than a dense scan of the ROI as illustrated in FIG. 2, measurement for the ROI 401 on the wafer level may be made at separate locations, e.g., locations 406a, 406b, and 406c (sometimes collectively referred to as locations 406), from a plurality of dies across the wafer. Because a scan is not performed across each location 406, each location 406 is illustrated as narrower than the ROI 101 shown in FIG. 1.

FIG. 5 illustrates a top plan view of a wafer 500 that includes a plurality of dies 502, with the ROI 401 illustrated in FIG. 4 on the wafer level, as illustrated by the variations in the shaded dies 504a, 504b, and 504c, which correspond to locations 406a, 406b and 406c shown in FIG. 4.

The SOI 402 and the unknown structure 404 may both have variations over the wafer-level ROI 401, but their variations may reside at different wavelength regions. Thus, in the wavelength region where the unknown structure 404 has large variation, the SOI may have little variation, and accordingly, it is possible to remove the undesired influences from the unknown structure 404 in the measurement of the SOI 402. In some implementations, the unknown structure 404 may be a non-periodic circuit, such as a CMOS circuit, or some other underlaying (overlying) circuit, and the SOI 402 may be a periodic structures such as V-NAND or DRAM structures. In other implementations, the unknown structure 404 may be periodic and may have the same (or different) periodicity as the SOI 402. For example, the sample may be a Chemical Mechanical Polishing (CMP) layer or some other backend layer where the interest is to measure the parameters of the SOI 402 in the top region and minimize the undesired influence from the unknown structure 404 in the bottom region. The unknown structure 404, alternatively, may be structures containing complex regions that were produced in earlier fabrication process steps, while the SOI 402 is in current fabrication process step.

Data collected from a plurality of locations across the wafer 500 (or ROI 401), e.g., on different dies 504a, 504b, and 504c, may vary considerably due to the variations of both the SOI 402 and the unknown structure 404 over the ROI 401.

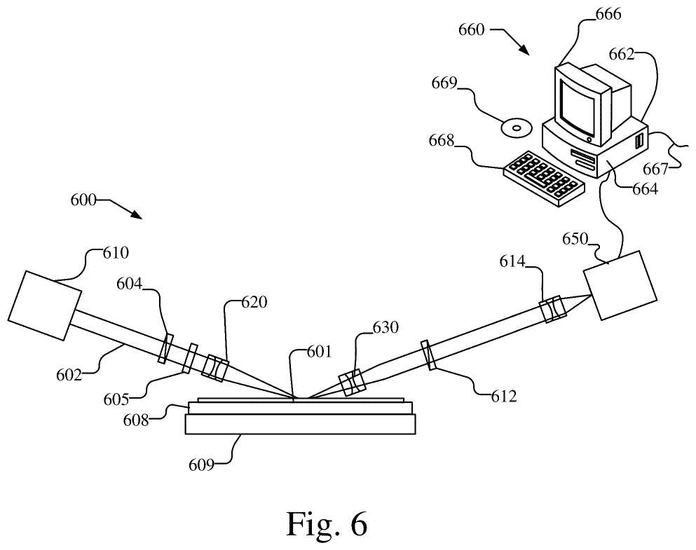

FIG. 6, by way of example, illustrates a schematic view of an optical metrology device 600 that may be used to generate and use an influence map of deviation contributions from an unknown structure of a sample for measuring one or more parameters of a SOI, as described herein. The optical metrology device 600 may be configured to perform, e.g., spectroscopic reflectometry, spectroscopic ellipsometry, interferometry, or FTIR measurements, of a sample 601 that includes a SOI having a known structure and a section having an unknown structure that is optically coupled to the SOI. It should be understood that optical metrology device 600 is illustrated as one example of a metrology device that may generate and/or use an influence map, as discussed herein, and that if desired other metrology devices may be used, including normal incidence devices, non-polarizing devices, etc.

Optical metrology device 600 includes a light source 610 that produces light 602. The light 602, for example, UV-visible light with wavelengths, e.g., between 200 nm and 800 nm. The light 602 produced by light source 610 may include a range of wavelengths, i.e., broadband, or may be monochromatic. The optical metrology device 600 includes focusing optics 620 and 630 that focus and receive the light and direct the light to be obliquely incident on a top surface of the sample 601. The optics 620, 630 may be refractive, reflective, or a combination thereof and may be an objective lens.

The reflected light may be focused by lens 614 and received by a detector 650. The detector 650, may be a conventional charge coupled device (CCD), photodiode array, CMOS, or similar type of detector. The detector 650 may be, e.g., a spectrometer if broadband light is used, and detector 650 may generates a spectral signal as a function of wavelength. A spectrometer may be used to disperse the full spectrum of the polarized light into spectral components across an array of detector pixels. One or more polarizing elements may be in the beam path of the optical metrology device 600. For example, optical metrology device 600 may include one or both (or none) of a polarizing element 604 in the beam path before the sample 601, and a polarizing element (analyzer) 612 in the beam path after the sample 601, and may include one or more additional elements, such as a compensator or photoelastic modulator 605.

The detector 650 may be coupled to at least one processor 660, which may be a workstation, a personal computer, or other adequate computer system, or multiple systems. It should be understood that one processor, multiple separate processors or multiple linked processors may be used, all of which may interchangeably be referred to herein as at least one processor 660, one or more processors 660, or simply processor 660. The at least one processor 660 is preferably included in or is connected to or otherwise associated with optical metrology device 600. The at least one processor 660, for example, may control the positioning of the sample 601, e.g., by controlling movement of a stage 609 that is coupled to the chuck. The stage 609, for example, may be capable of horizontal motion in either Cartesian (i.e., X and Y) coordinates, or Polar (i.e., R and θ) coordinates or some combination of the two. The stage may also be capable of vertical motion along the Z coordinate. The at least one processor 660 may further control the operation of the chuck 608 to hold or release the sample 601. The at least one processor 660 may also collect and analyze the data obtained from the detector 650. The at least one processor 660 may analyze the data to generate an influence map for the deviation contributions from an unknown structure of a sample, produce a model for the sample, including a rigorous model for the SOI and an effective model for the unknown structure, and/or to use the influence map and model to measure one or more parameters of the sample 601, as discussed herein. For example, the at least one processor 660 may collect scanned data from the sample and process the data to determine and store for each scanned location the deviation contribution from the unknown structure to produce the influence map. The at least one processor 660 may be used to generate and store a model of the sample including a rigorous model for the SOI and an effective model for the unknown structure after the deviation contribution is removed. The at least one processor 660 further may be used to process data measured from a measurement site on a sample using the influence map to remove the deviation contribution from the unknown structure at the measurement site, and to compare the processed data to the predicted data generated with the model of the sample that includes the rigorous model of the SOI and the effective model for the unknown structure. Predicted data for variations of the model parameters may be compared to the measured data, e.g., in a nonlinear regression process, until a good fit is achieved between the predicted data and the measured data, at which time the fitted parameters are determined to accurately describe the parameters of the SOI.

The at least one processor 660, which includes at least one processing unit 662, such as a central processing unit, with memory 664, as well as a user interface including e.g., a display 666 and input devices 668. A non-transitory computer-usable storage medium 669 having computer-readable program code embodied thereon that when executed by the at least one processor 660 causes the at least one processor 660 to control the optical metrology device 600 and to perform the functions including the analysis described herein. The data structures and software code for automatically implementing one or more acts described in this detailed description can be implemented by one of ordinary skill in the art in light of the present disclosure and stored, e.g., on a computer-usable storage medium 669, which may be any device or medium that can store code and/or data for use by a computer system such as processing unit 662. The computer-usable storage medium 669 may be, but is not limited to, flash drive, magnetic and optical storage devices such as disk drives, magnetic tape, compact discs, and DVDs (digital versatile discs or digital video discs). A communication port 667 may also be used to receive instructions that are used to program the at least one processor 660 to perform any one or more of the functions described herein and may represent any type of communication connection, such as to the internet or any other computer network. The communication port 667 may further export signals, e.g., with measurement results and/or instructions, to another system, such as external process tools, in a feed forward or feedback process in order to adjust a process parameter associated with a fabrication process step of the samples based on the measurement results. Additionally, the functions described herein may be embodied in whole or in part within the circuitry of an application specific integrated circuit (ASIC) or a programmable logic device (PLD), and the functions may be embodied in a computer understandable descriptor language which may be used to create an ASIC or PLD that operates as herein described. The results from the analysis of the data may be reported, e.g., stored in memory 664 associated with the sample 601 and/or indicated to a user via display 666, an alarm or other output device. Moreover, the results from the analysis may be reported and fed forward or back to the process equipment to adjust the appropriate fabrication steps to compensate for any detected variances in the fabrication process.

A sample that includes a SOI and an unknown structure, e.g., as illustrated in FIGS. 1 and 4, may be measured, e.g., using an optical metrology device, such as illustrated in FIG. 6, by minimizing the undesired/unknown influence of the unknown structure on the measured data. For example, an influence map of deviation contributions associated with multiple locations within an ROI of the sample may be produced using various data processing techniques. Even with the deviation contribution due to the unknown structure removed from the measured data, a base contribution from the unknown structure will remain in the measured data. The base contribution due to the unknown structure may be modeled using an effective model, which is combined with a rigorous model for the SOI.

An influence map for the unknown structure that may be useful in the measurement of the SOI across multiple ROIs on a wafer and across multiple wafers may be particularly useful if, according to a first condition (condition I), the unknown structure is repeatable from ROI to ROI. Thus, an influence map extracted from one ROI can be applied to other ROIs on the same wafer and/or other wafers.

If the ROI is on die level, the SOI may have little or no in-ROI process variation during fabrication, i.e., the SOI is consistent within each ROI, while the unknown structure may have large in-ROI variation, as illustrated in FIG. 1. After subtracting the deviation contributions retrieved from the influence map of the unknown structure from the measured data, the remaining data should be consistent within the ROI. Thus, this condition (condition II) may be used to validate if the extracted influence map of the unknown structure is accurate. If the ROI is on wafer level, the SOI and the unknown structure may both have variations over the ROI and produce deviation contributions to the measured data. If the deviation contributions in the measured data for the SOI and the unknown structure reside at different wavelength regions, e.g., the unknown structure produces large deviation contributions in a specific wavelength region in which the SOI produces little deviation contributions, it is possible to remove the influence of the unknown structure on the measured data by subtracting the deviation contributions from the unknown structure over the specific wavelength that is retrieved from the influence map of the unknown structure. Condition II can also be used to validate the accuracy of the influence map extracted from the wavelength region where the unknown structure has big variation while the SOI has little variation.

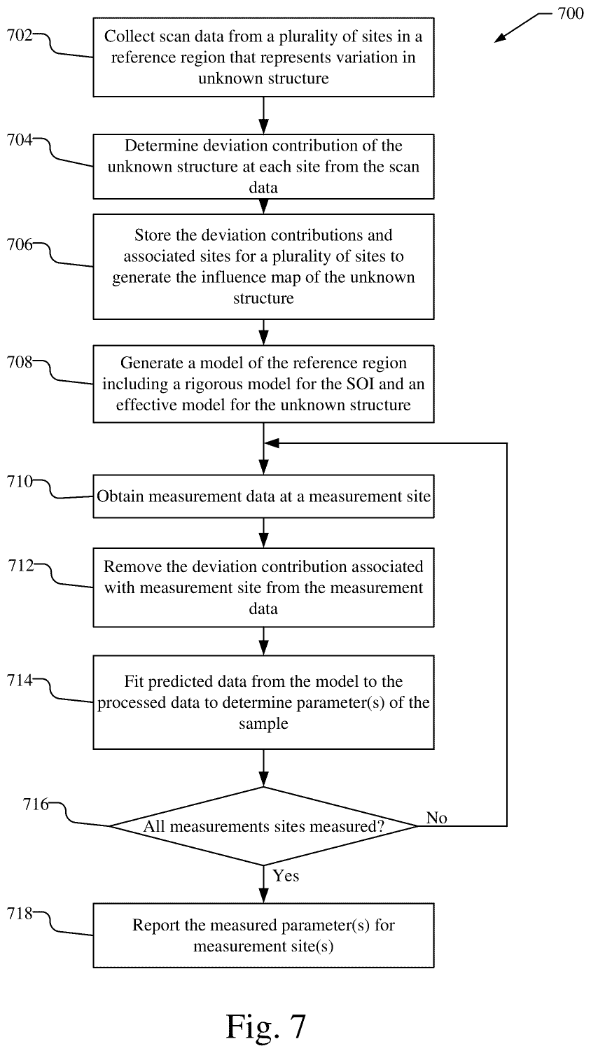

FIG. 7 illustrates a flow chart 700 of a process of measuring a sample that includes a SOI with a known structure and a section having an unknown structure, e.g., as illustrated in FIGS. 1 and 4, by generating and using an influence map and building and using an effective model for the unknown structure.

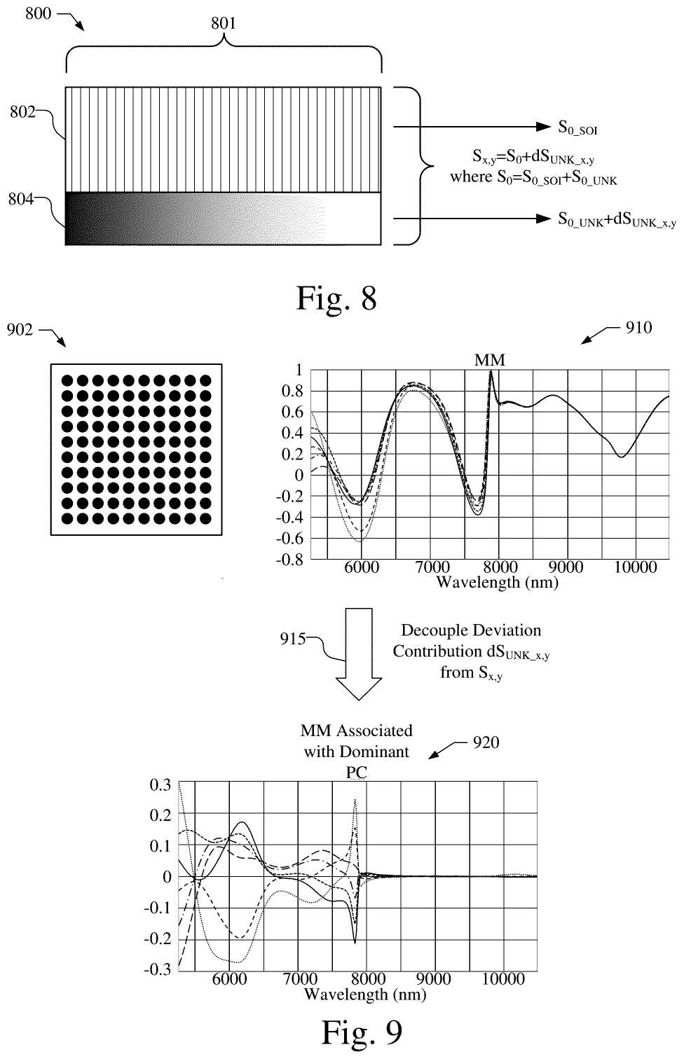

As illustrated at block 702, data is collected from a scan of the sample at a plurality of sites in a reference region that represents the variation in the unknown structure. FIG. 8, by way of example, illustrates a reference region, e.g., ROI 801, of a sample 800 that includes a SOI 802 and an unknown structure 804, similar to that shown in FIG. 1. The reference region may thus be a ROI within a single die, e.g., as illustrated in FIG. 2, or may be a ROI over the entire wafer, e.g., as illustrated in FIGS. 4 and 5.

The data may be collected with a dense scan over the ROI 801, illustrated in FIG. 8 or may be collected over a ROI that includes the entire wafer as shown in FIGS. 4 and 5.

FIG. 9, by way of example, illustrates a plurality of locations 902 in the ROI 801 from which measurement data are collected. The graph 910, by way of example, is similar to graph 300 shown in FIG. 3 and illustrates examples of data that may be collected from the locations 902 in the ROI 801. The graph 910, illustrates the MM spectral data, where each curve represents the spectral data collected from a different location. For ease of reference, the collected data may sometimes be referred to herein as spectral data. It should be understood, however, that the collected data may be ellipsometric data, reflectometric data, interferometric data, FTIR data, or any other type of data that may be used to measure parameters of a sample via modeling.

The optical data collected from each location in the reference region is a complex combination of the response from the SOI and the unknown structure. The signal from the unknown structure is coupled with that of the SOI in a complicated manner, which is difficult to decouple. For example, assuming spectral data is collected from each site, the overall spectra(S) measured from each site is a combination of the response from the SOI (S_{SOI}) and the unknown structure (S_{UNK}), so the spectra(S) may be expressed as the following simple equation, wherein the symbol “+” indicates a combination.

$$S = {S}_{SOI} + {S}_{UNK} \qquad eq . 1$$

The component of the measured spectra may be decomposed into a base contribution (S₀) and a deviation contribution (dS) from the base spectra. The base contribution S₀ is a constant within the ROI, while the deviation contribution dS varies from site to site within the ROI. Accordingly, equation 1 may be written as follows.

$$S = {S}_{0 \_ SOI} + {dS}_{SOI} + {S}_{0 \_ UNK} + {dS}_{UNK} \qquad eq . 2$$

As discussed above with respect to condition II, if the ROI is on the die level, the SOI has negligible in-ROI variation. Moreover, while the SOI may have variation over the ROI, if the ROI is on the wafer level, the deviation contribution dS produced by the SOI may be limited to specific wavelength regions, which may be excluded from the influence map. Accordingly, the deviation contribution dS component for the SOI may be assumed to be 0. Moreover, as discussed above with respect to condition I, the unknown structure varies across the ROI, and thus, in-ROI variation in the measured data will vary due primarily to the deviation contribution dS component from the unknown structure. The base contribution component of the data produced by the SOI (S_{0_SOI}) and the base contribution component of the data produced by the unknown structure (S_{0_UNK}) may be combined, and equation 2 may be re-written as follows.

$$S = {S}_{0} + {dS}_{UNK} , \\ where {S}_{0} = {S}_{0 \_ SOI} + {S}_{0 \_ UNK} \qquad eq . 3$$

As illustrated in FIG. 8, the SOI 802 contributes the base contribution component S_{0_SOI} of the data, which does not vary over the ROI 801 if the ROI is on the die level, and may not vary over specific wavelength regions if the ROI is on the wafer level. The unknown structure 804 also contributes a base contribution component S_{0_UNK} of the data that does not vary across the ROI. Due to the variation in the unknown structure 804 across the ROI 801, however, each location (x,y) within the ROI 801 from which data is collected will have a different deviation contribution component dS_{UNK_x,y}, which is contributed by the variation of the unknown structure 804 over ROI 801 and that is combined with the base component S_{0_UNK}. Accordingly, the data collected from the sample will differ for each location (x,y) due primarily to the variation in the deviation contribution component dS_{UNK_x,y}, and as illustrated in FIG. 8, the data collected for each position S_{x,y} may be written as follows.

$${S}_{x , y} = {S}_{0} + {dS}_{UNK \_ x , y} \\ where {S}_{0} = {S}_{0 \_ SOI} + {S}_{0 \_ UNK} \qquad eq . 4$$

At block 704, the deviation contribution dS_{UNK_x,y} at each location in the reference region is determined using the collected scan data S_{x,y}. It is desirable to determine and remove the influence of the deviation contribution dS_{UNK_x,y} from the unknown structure for each location so that only the base contribution S₀ from the SOI and the unknown structures remain. Thus, at block 704, the deviation contribution dS_{UNK_x,y} for each location from which data is collected may be determined by decoupling the deviation contribution dS_{UNK_x,y} from the base contribution S₀ at each location (x,y) using at least one of Principal Component Analysis (PCA), Independent Component Analysis (ICA), Partial Least Squares (PLS), etc., or a combination thereof, e.g., as illustrated by arrow 915 in FIG. 9.

For example, using PCA with collected scan data may produce a number of principal components (PCs), each having an associated score. One or more dominant PCs together with the corresponding scores on these PCs may be selected as representing the deviation contribution dS_{UNK_x,y}, e.g., based on a sum of the dominant PCs multiplied by their corresponding scores. For example, the ranks of the PCs may be used to identify the dominant PCs based on the highest ranking PCs, which may be used to represent the deviation contribution dS_{UNK_x,y}. For example, the N highest ranking PCs may be considered the dominant PCs, where N may be 5, 10, 15, etc. In another implementation, the highest ranking X percent of PCs may be considered the dominant PCs, where X may be 10%, 20%, 30%, etc. If desired, the dominant PCs may be determined in another manner, such as based on the PCs with weights greater than a predetermined threshold, etc. The dominant PCs carry the most signals associated with the deviation contribution dS_{UNK_x,y} from the unknown structure for each location. In other examples, one or more of the PCs used to represent the deviation contribution dS_{UNK_x,y} may be selected based on criteria other than the highest ranks. For example, a PC being more correlated with the unknown structure and less correlated to the SOI, but may have a relatively low rank, or a PC with a high rank may be more correlated with the SOI and less correlated with the unknown structure. Thus, one or more PCs may be selected to represent the deviation contribution dS_{UNK_x,y} based on its correlation to the unknown structure, or other similar criteria.

In some implementations, the analysis to decouple the deviation contribution dS_{UNK_x,y} from the base contribution S₀ at each location (x,y) may be over a limited data range, e.g., that is sensitive to the unknown structure. For example, as illustrated in FIG. 9, the collected data is sensitive to the unknown structure over a limited wavelength range between 5,300 nm and 7,800 nm and, accordingly, processing of the collected data to decouple the deviation contribution may be limited to that wavelength range. It should be understood that algorithms other than PCA, such as ICA, PLS, etc., or some combination of algorithms may also be used to decouple the deviation contribution dS_{UNK_x,y} from the base contribution S₀ at each location (x,y).

Graph 920 in FIG. 9, by way of example, illustrate examples of the deviation contribution from the unknown structure associated with dominant PCs for each location dS_{UNK_x,y}. Removing the deviation contribution associated with dominant PCs from the S_{x,y} produces data with little or no variation over the ROI, i.e., the data includes base contributions from the SOI 802 and the unknown structure 804 (S₀=S_{0_SOI}+S_{0_UNK}) with little or no deviation contribution dS_{UNK_x,y}.

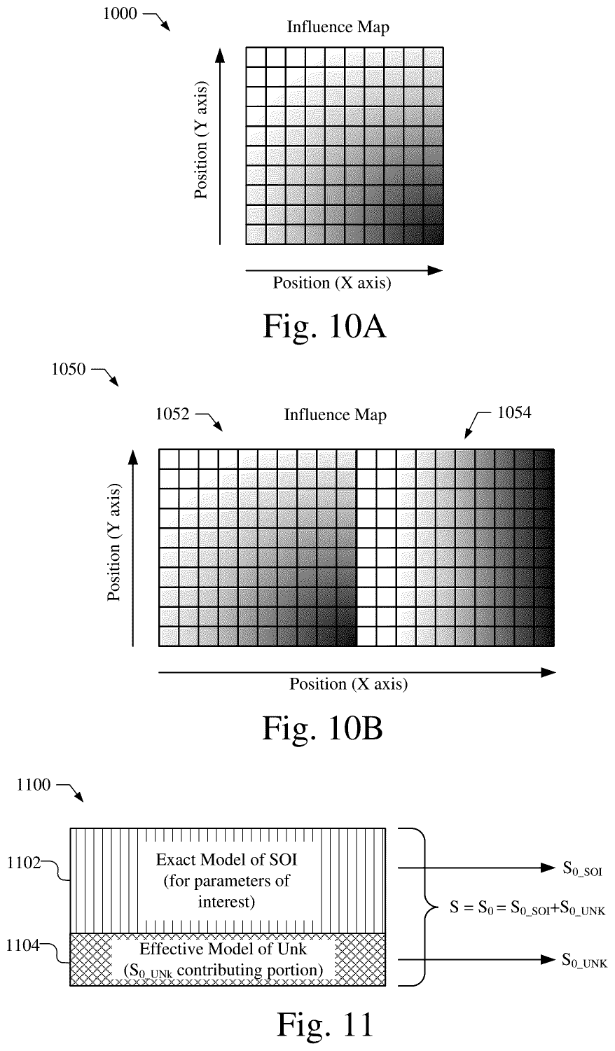

At block 706, the deviation contributions dS_{UNK_x,y} and its associated locations (x,y) for the plurality of locations are stored in a library or look-up table, which may be referred to as the influence map. FIG. 10A, by way of example, graphically illustrates an influence map 1000 for the deviation contribution dS_{UNK_x,y} associated with each location (x,y) in a reference region, i.e., ROI, where the shading in the influence map 1000 represents different deviation contributions dS_{UNK}. In some implementations, a single influence map is unable to cover all the deviation contributions dS_{UNK_x,y} in a ROI, especially when the deviation contributions dS_{UNK_x,y} have large discontinuities or gaps between multiple sub-regions, e.g., locations, within the ROI. In this case, a separate influence map may be generated for each location, and the influence maps of the locations may be stitched together to form the whole influence map. For example, FIG. 10B illustrates an influence map 1050 that includes a first influence map 1052 for a first location in the ROI and a second influence map 1054 for a second location in the ROI, where the first influence map 1052 and second influence map 1054 are independently generated and stitched together.

Moreover, in some implementations, an influence map, such as influence map 1000 illustrated in FIG. 10A may be generated based on a statistical combination of a number of independently generated influence maps. For example, separate influence maps may be generated based on data collected from multiple ROIs, e.g., from different dies on a wafer and/or from different wafers. The separate influence maps may then be combined together to produce a single influence map 1000, e.g., by averaging the separate influence maps or summing the separate influence maps with different weights. By generating multiple influence maps that are then statistically combined to produce a single influence map, the resulting influence map may account for fabrication variations of the unknown structure that may occur over different dies on a wafer and/or different wafers. In some implementations, the data collected at block 702 may be from corresponding locations in a plurality of separate reference regions and may be collectively used to produce a single influence map 1000. In other implementations, the process conditions on the unknown structure may change significantly across different ROIs, e.g., the design on the unknown structure may change from one wafer to another. In this case, a separate influence map may be generated based on the data collected from each ROI, and the influence maps of the plurality of ROIs may be saved to a library or look-up table. When taking the measurements, each individual influence map will be used for the measurement sites corresponding to the ROI from which the influence map is generated.

At block 708, a model for the sample is generated that includes a rigorous model for the SOI 802 and an effective model for the base contribution component S_{0_UNK} of the unknown structure 804. The rigorous model for the SOI 802 is an accurate representation of the physical structure of the SOI 802 with one or more variable parameters. An effective model for the unknown structure 804, on the other hand, does not attempt to accurately represent the physical structure of the unknown structure 804 (which is not known), but instead is a representation of a structure that is capable of producing the base component S_{0_UNK} of the signal, but does not produce the deviation contribution dS_{UNK}. The effective model may be generated, for example, based on an approximation of the unknown structure 804 with one or more variable parameters. The deviation contribution dS_{UNK} at one or more locations may be removed from the data S measured at each location to generate the total base component, i.e., S_{0_SOI}+S_{0_UNK}, which may be fit by the predicted data from the rigorous model of the SOI 802 and the effective model of the unknown structure 804. The structure, materials, and variable parameters of the effective model may be varied until an acceptable fit can be achieved.

FIG. 11, by way of example, illustrates an example of a model 1100 of the sample 800 illustrated in FIG. 8, that includes a rigorous model 1102 for the SOI 802 and an effective model 1104 for the base contribution component S_{0_UNK} of the unknown structure 804. Thus, when the predicted data S is generated using model 1100, the rigorous model 1102 for the SOI 802 contributes the base component S_{0_SOI} of the predicted data, while the effective model 1104 for the unknown structure 804 contributes the base component S_{0_UNK}. The base contribution component does not vary over the ROI 801, and accordingly, the predicted data S is the combined base components, i.e., S=S₀=S_{0_SOI}+S_{0_UNK}.

With the influence map for the ROI and a model of the sample (including a rigorous model for the SOI and an effective model for the base contribution component S_{0_UNK} of the unknown structure) generated, one or more locations of a sample within a corresponding ROI, e.g., containing the SOI and unknown structure, may be optically measured. The measured sample, for example, may be on the same wafer that was used to generate the influence map and model of the sample or may be on a different wafer.

At block 710 of FIG. 7, for example, measurement data may be obtained from a measurement site on a sample under test. The measurement data may be obtained, for example, using the same metrology device or similar metrology device as used to collect the data at block 702. Moreover, the measured data is collected from a measurement site that corresponds to a location in a ROI from which the data was collected at block 702 and that is included in the influence map.

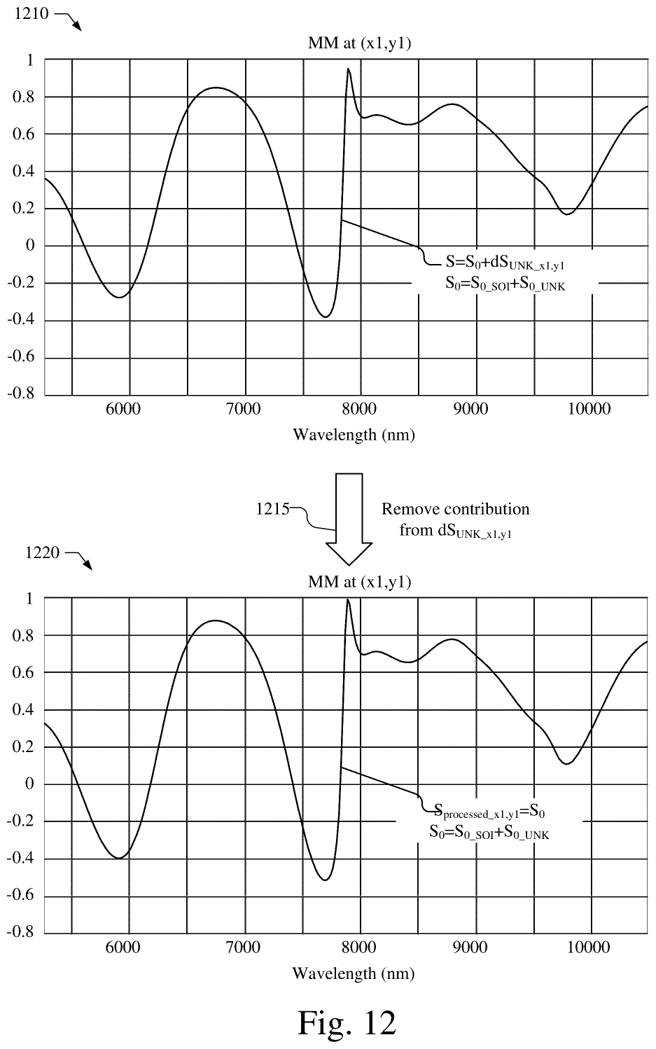

FIG. 12, for example, illustrates a graph 1210 of measurement data that may be obtained from a measurement site on a sample under test. Graph 1210, by way of example, is similar to graph 910 shown in FIG. 9 and graph 300 shown in FIG. 3 and but illustrates an example of spectral data for a Mueller matrix element that may be collected from a single location (x1,y1) on a sample. As discussed above, the data collected at location (x1,y1) includes a combination of the response signal from the SOI (S_{0_SOI}) and response signal from the unknown structure at location (x1,y1) (S_{0_UNK}+dS_{UNK_x1,y1}) and may be written as follows.

$${S}_{x 1 , y 1} = {S}_{0} + {dS}_{UNK \_ x 1 , y 1} \\ where {S}_{0} = {S}_{0 \_ SOI} + {S}_{0 \_ UNK} \qquad eq . 5$$

While FIG. 12 illustrates the collected data as a single MM element, it should be understood that the metrology data may be ellipsometric data like Psi & Delta data, Jones matrix, etc., reflectometric data like reflectance collected at different polarizer angles and/or different angles of incidence (AOIs), interferometric data like spectra in frequency domain, FTIR data etc., and the collected data should be the same as used to generate the influence map, e.g., as blocks 704 and 706 of FIG. 7.

At block 712 of FIG. 7, the deviation contribution associated with the measurement site, i.e., at location (x1,y1), is removed from the collected measurement data. For example, deviation contribution associated with location (x1,y1) may be obtained from the influence map generated at blocks 704 and 706 of FIG. 7. The deviation contribution may be removed from the collected measurement data, e.g., by subtracting the deviation contribution from the collected measurement data. If desired other processing techniques may be used to remove the deviation contribution from the collected measurement data.

FIG. 12, by way of example, illustrates with arrow 1215 the processing of the collected data to remove the deviation contribution dS_{UNK_x1,y1} to generate the processed data in graph 1220. The processed data in graph 1220 is similar to the collected data from graph 1210, but it has the deviation contribution dS_{UNK_x1,y1} removed, which may be written as follows.

$${S}_{processed \_ x 1 , y 1} = {S}_{0} \\ where {S}_{0} = {S}_{0 \_ SOI} + {S}_{0 \_ UNK} \qquad eq . 6$$

At block 714 of FIG. 7, the modeled data generated from the rigorous and effective models is fit to the processed data to determine one or more parameters for the sample. The modeled data, for example, is produced using the rigorous model of the SOI 802 and the effective model for the base contribution component S_{0_UNK} of the unknown structure 804 obtained from block 708 in FIG. 7. The modeled data S_{modeled}, thus, is a combination of rigorously modeled data for the base component S_{0_SOI_Rigorous} for the SOI 802 and the effectively modeled data for the base component S_{0_UNK_Effective} for the unknown structure 804. The modeled data S_{modeled}, for example, may be generated using RCWA, FDTD, FEM, etc., from the model of the sample.

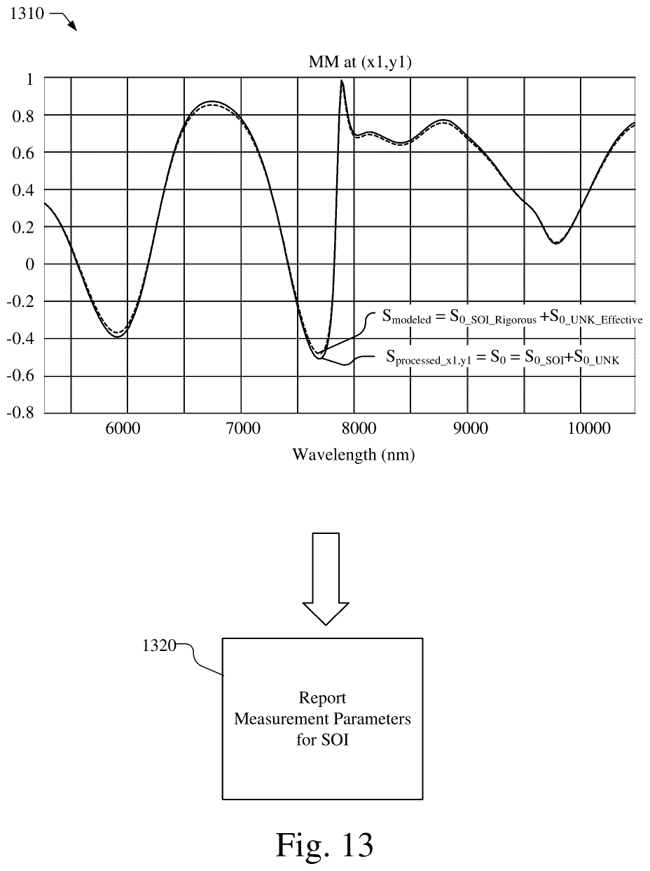

FIG. 13, by way of example, illustrates a graph 1310 including an example fit of the modeled data S_{modeled} to the processed data S_{processed_x1,y1}.

Modeled data S_{modeled}, for example, is generated for different variable parameter values for the rigorous model of the SOI 802 and the effective model for the base contribution component S_{0_UNK} of the unknown structure 804, which may be stored in a library, or may be calculated in real time. The processed data S_{processed_x1,y1} may be compared to the modeled data S_{modeled} stored in the library or determined in real time to find a best fit, e.g., based on the Mean-Squared Error (MSE). When a best fit is found, the values of the variable parameters of the rigorous model of the SOI 802 may be assumed to accurately describe the SOI under test.

At block 716, if additional measurement sites are to be measured, the process returns to block 710 for a new measurement location on the sample, e.g., after moving the sample and/or optics of the metrology device to measure the new location, and the process repeats. If there are no additional measurement sites to be measured, at block 718, the measured parameters for the measurement site(s) may be reported, e.g., as illustrated by block 1320 in FIG. 13. As discussed above, the report for the measurement parameters may include storing the results, providing an indication of the results to a user, e.g., via a display, alarm, etc., or feeding the results forward or back to adjust the appropriate fabrication steps.

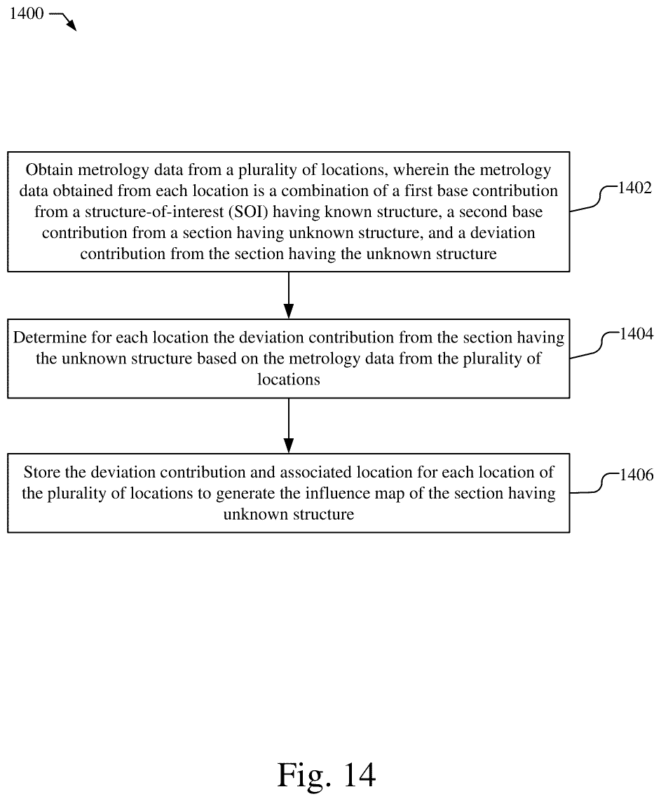

FIG. 14 is a flow chart 1400 illustrating a method of producing an influence map for optical measurement of a sample, as discussed herein.

At block 1402, metrology data is obtained from a plurality of locations, wherein the metrology data obtained from each location is a combination of a first base contribution from a structure-of-interest (SOI) having known structure, a second base contribution from a section having unknown structure, and a deviation contribution from the section having the unknown structure, e.g., as discussed at block 702 of FIG. 7 and in reference to FIGS. 8 and 9. The metrology data, for example, may include ellipsometric data, reflectometric data, interferometric data, FTIR data, or a combination thereof. By way of example, in some implementations, the plurality of locations may be within a region-of-interest (ROI) and the deviation contribution from the section having the unknown structure varies across the ROI, e.g., as discussed in reference to FIGS. 8 and 9. The ROI, for example, may be within a die on a wafer, or in another example, the ROI may be one or more measurement sites from a plurality of dies across the wafer. The section having the unknown structure, for example, may reside at a region that underlies the SOI, is on top of the SOI, or is besides the SOI, or any combination thereof. A means for obtaining metrology data from a plurality of locations, wherein the metrology data obtained from each location is a combination of a first base contribution from a structure-of-interest (SOI) having known structure, a second base contribution from a section having unknown structure, and a deviation contribution from the section having unknown structure, for example, may be the optical metrology device 600 shown in FIG. 6 or other similar device.

At block 1404, for each location, the deviation contribution from the section having the unknown structure is determined based on the metrology data from the plurality of locations, e.g., as discussed at block 704 of FIG. 7 and in reference to FIG. 9. A means for determining for each location the deviation contribution from the section having unknown structure based on the metrology data from the plurality of locations, for example, may be one or more processors 660 with dedicated hardware or implementing executable code or software instructions in memory 664 or non-transitory computer-usable storage medium 669 shown in FIG. 6. In some implementations, the determining for each location the deviation contribution from the section having the unknown structure based on the metrology data from the plurality of locations may include decoupling the deviation contribution from a combination of the first base contribution and the second base contribution. For example, decoupling the deviation contribution from a combination of the first base contribution and the second base contribution may include the use of at least one of Principal Component Analysis (PCA), Independent Component Analysis (ICA), Partial Least Squares (PLS), or a combination thereof with the metrology data obtained from the plurality of locations. A means for means for decoupling the deviation contribution from a combination of the first base contribution and the second base contribution using at least one of Principal Component Analysis (PCA), Independent Component Analysis (ICA), Partial Least Squares (PLS), or a combination thereof with the metrology data obtained from the plurality of locations, for example, may be one or more processors 660 with dedicated hardware or implementing executable code or software instructions in memory 664 or non-transitory computer-usable storage medium 669 shown in FIG. 6.

At block 1406, the deviation contribution and associated location for each location of the plurality of locations are stored to generate the influence map of the section having unknown structure, e.g., as discussed at block 706 and in reference to FIGS. 10A and 10B. A means for storing in the memory the deviation contribution and associated location for each location of the plurality of locations to generate the influence map of the section having unknown structure, for example, may be one or more processors 660 with dedicated hardware or implementing executable code or software instructions in memory 664 or non-transitory computer-usable storage medium 669 shown in FIG. 6.

In some implementations, the plurality of locations may be in a plurality of regions-of-interest (ROIs). Additionally, an influence map may be determined for each ROI, and the influence map for each ROI may be combined to form the influence map, e.g., as discussed in reference to FIG. 10A. A means for determining an influence map for each ROI and means for combining the influence map for each ROI, for example, may be one or more processors 660 with dedicated hardware or implementing executable code or software instructions in memory 664 or non-transitory computer-usable storage medium 669 shown in FIG. 6. Alternatively, an influence map may be determined for each ROI and the influence maps for the plurality of ROIs may be saved to a library or look-up table. A means for determining an influence map for each ROI and means for saving the influence maps for the plurality of ROIs to a library or look-up table, for example, may be one or more processors 660 with dedicated hardware or implementing executable code or software instructions in memory 664 or non-transitory computer-usable storage medium 669 shown in FIG. 6. Each individual influence map, for example, may be used for the measurement sites corresponding to the ROI from which the influence map is determined. The plurality of ROIs, for example, may be located over multiple dies of a same wafer, multiple wafers, or a combination thereof.

In some implementations, the plurality of locations may be in a plurality of locations within a same ROI, and an influence map for each location in the plurality of locations may be determined and the influence maps for the plurality of locations may be stitched together, e.g., as discussed in reference to FIG. 10B. A means for determining an influence map for each location in the plurality of locations in the ROI and means for stitching together influence maps for the plurality of locations, for example, may be one or more processors 660 with dedicated hardware or implementing executable code or software instructions in memory 664 or non-transitory computer-usable storage medium 669 shown in FIG. 6.

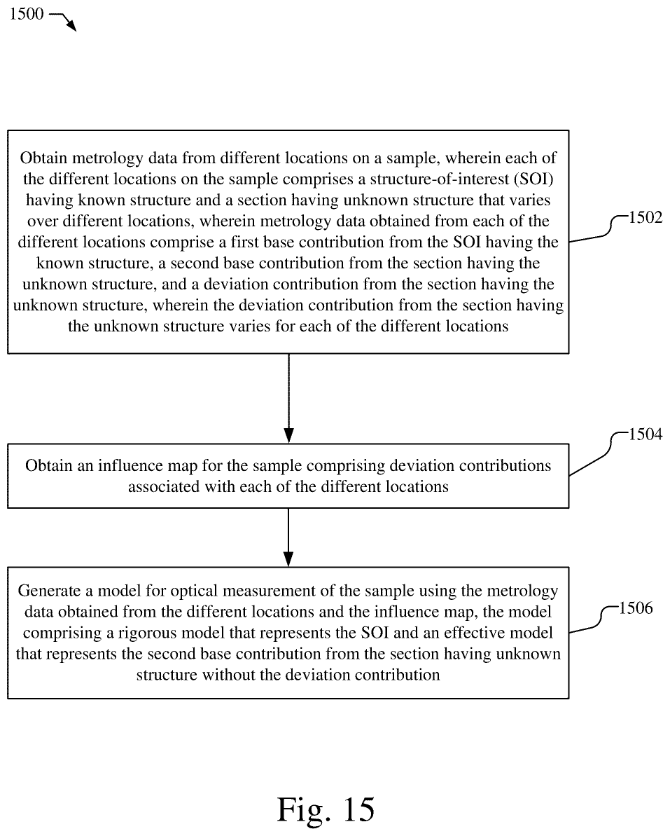

FIG. 15 is a flow chart 1500 illustrating a method of producing a model for optical measurement of a structure-of-interest (SOI) on a sample, as discussed herein.

At block 1502, metrology data is obtained from different locations on a sample, wherein each of the different locations on the sample comprises the SOI having known structure and a section having unknown structure that varies over different locations, wherein metrology data obtained from each of the different locations comprise a first base contribution from the SOI having the known structure, a second base contribution from the section having the unknown structure, and a deviation contribution from the section having the unknown structure, wherein the deviation contribution from the section having the unknown structure varies for each of the different locations, e.g., as discussed at blocks 702, 704, and 706 of FIG. 7 and in reference to FIGS. 8, 9, 10A, 10B. The metrology data, for example, may include ellipsometric data, reflectometric data, interferometric data, FTIR data, or a combination thereof. By way of example, in some implementations, the plurality of locations may be within a region-of-interest (ROI) and the deviation contribution from the section having the unknown structure varies across the ROI, e.g., as discussed in reference to FIGS. 8 and 9. The ROI, for example, may be within a die on a wafer, or in another example, the ROI may be a wafer and the plurality of locations is across the wafer. The section having the unknown structure, for example, may reside at a region that underlies the SOI, is on top of the SOI, or is besides the SOI, or any combination thereof. A means for obtaining metrology data from different locations on the sample, wherein each of the different locations on the sample comprises the SOI having known structure and a section having unknown structure that varies over the different locations, wherein metrology data obtained from each of the different locations comprise a first base contribution from the SOI having the known structure, a second base contribution from the section having unknown structure, and a deviation contribution from the section having unknown structure, wherein the deviation contribution from the section having unknown structure varies for each of the different locations, for example, may be the optical metrology device 600 shown in FIG. 6 or other similar device.

At block 1504, an influence map for the sample is obtained, the influence map comprises the deviation contribution associated with each of the different locations, e.g., as discussed at blocks 702, 704, and 706 of FIG. 7 and in reference to FIGS. 8, 9, 10A, 10B. A means for obtaining an influence map for the sample comprising deviation contributions associated with each of the different locations, for example, may be one or more processors 660 with dedicated hardware or implementing executable code or software instructions in memory 664 or non-transitory computer-usable storage medium 669 shown in FIG. 6.

At block 1506, a model for optical measurement of the SOI is generated using the metrology data obtained from the different locations and the influence map. The model comprises a rigorous model that represents the SOI and an effective model that represents the second base contribution from the section having unknown structure without the deviation contribution, e.g., as discussed at block 708 and in reference to FIG. 11. A means for generating the model for optical measurement of the SOI using the metrology data obtained from the different locations and the influence map, the model comprising a rigorous model that represents the SOI and an effective model that represents the second base contribution from the section having unknown structure without the deviation contribution, for example, may be one or more processors 660 with dedicated hardware or implementing executable code or software instructions in memory 664 or non-transitory computer-usable storage medium 669 shown in FIG. 6.

In some implementations, the model for optical measurement of the SOI may be generated by removing the deviation contribution from the metrology data from each of the different locations to generate processed metrology data comprising the combination of the first base contribution from the SOI and the second base contribution from the section having unknown structure without the deviation contribution. The effective model is developed based on the processed metrology data, e.g., as discussed at block 708 and in reference to FIG. 11. A means for removing the deviation contribution from the metrology data obtained from each of different locations to generate processed metrology data comprising a combination of the first base contribution from the SOI and the second base contribution from the section having unknown structure without the deviation contribution, for example, may be one or more processors 660 with dedicated hardware or implementing executable code or software instructions in memory 664 or non-transitory computer-usable storage medium 669 and in FIG. 6. A means for developing the model based on the processed metrology data, for example, may be one or more processors 660 with dedicated hardware or implementing executable code or software instructions in memory 664 or non-transitory computer-usable storage medium 669 shown in FIG. 6.

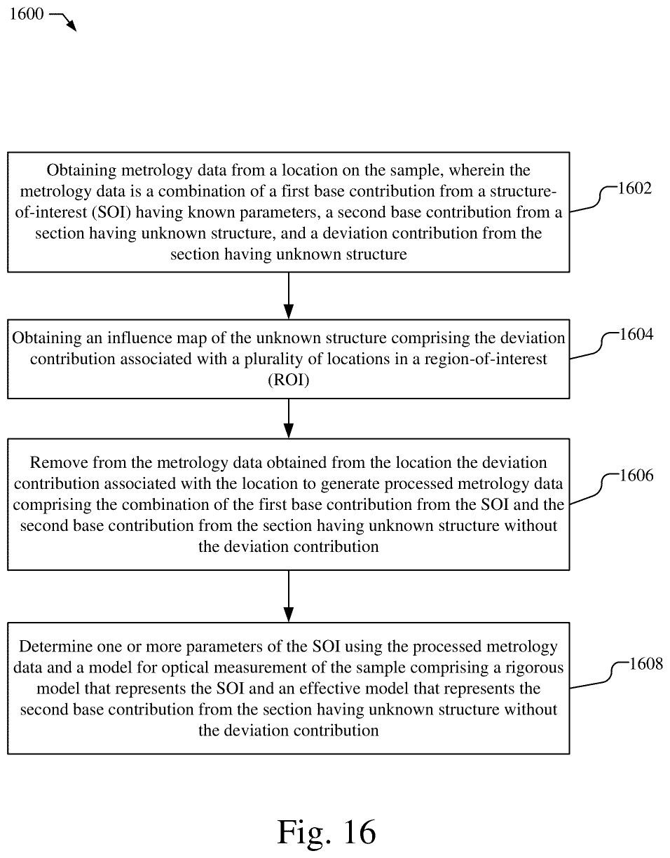

FIG. 16 is a flow chart 1600 illustrating a method of optical measurement of a sample, as discussed herein.

At block 1602, metrology data from a location on the sample is obtained, wherein the metrology data is a combination of a first base contribution from a structure-of-interest (SOI) having known parameters, a second base contribution from a section having unknown structure, and a deviation contribution from the section having unknown structure, e.g., as discussed at block 710 of FIG. 7 and in reference to FIG. 12. The metrology data, for example, may include ellipsometric data, reflectometric data, interferometric data, FTIR data, or a combination thereof. By way of example, in some implementations, the plurality of locations may be within a region-of-interest (ROI) and the deviation contribution from the section having the unknown structure varies across the ROI, e.g., as discussed in reference to FIGS. 8 and 9. The ROI, for example, may be within a die on a wafer, or in another example, the ROI may be a wafer and the plurality of locations is across the wafer. The section having the unknown structure, for example, may reside at a region that underlies the SOI, is on top of the SOI, or is besides the SOI, or any combination thereof. A means for obtaining metrology data from a location on the sample, wherein the metrology data is a combination of a first base contribution from a structure-of-interest (SOI) having known parameters, a second base contribution from a section having unknown structure, and a deviation contribution from the section having unknown structure, for example, may be the optical metrology device 600 or other similar device, with one or more processors 660 with dedicated hardware or implementing executable code or software instructions in memory 664 or non-transitory computer-usable storage medium 669 shown in FIG. 6.

At block 1604, an influence map for the sample is obtained comprising the deviation contribution associated with a plurality of locations on the sample, e.g., as discussed at blocks 702, 704, and 706 of FIG. 7 and in reference to FIGS. 8, 9, 10A, 10B. A means for obtaining an influence map for the sample comprising the deviation contribution associated with a plurality of locations on the sample, for example, may be the one or more processors 660 with dedicated hardware or implementing executable code or software instructions in memory 664 or non-transitory computer-usable storage medium 669 shown in FIG. 6.

At block 1606, the process includes the deviation contribution associated with the location is removed from the metrology data obtained from the location to generate the processed metrology data comprising the combination of the first base contribution from the SOI and the second base contribution from the section having unknown structure without the deviation contribution, e.g., as discussed at block 712 of FIG. 7 and in reference to FIG. 12. A means for removing from the metrology data obtained from the location the deviation contribution associated with the location to generate processed metrology data comprising the combination of the first base contribution from the SOI and the second base contribution from the section having unknown structure without the deviation contribution, for example, may be the one or more processors 660 with dedicated hardware or implementing executable code or software instructions in memory 664 or non-transitory computer-usable storage medium 669 shown in FIG. 6.

At block 1608, one or more parameters of the SOI is determined using the processed metrology data and a model for optical measurement of the SOI comprising a rigorous model that represents the SOI and an effective model that represents the second base contribution from the section having unknown structure without the deviation contribution, e.g., as discussed at block 714 of FIG. 7 and in reference to FIG. 13. A means for determining one or more parameters of the SOI using the processed metrology data and a model for optical measurement of the SOI comprising a rigorous model that represents the SOI and an effective model that represents the second base contribution from the section having unknown structure without the deviation contribution, for example, may be the one or more processors 660 with dedicated hardware or implementing executable code or software instructions in memory 664 or non-transitory computer-usable storage medium 669 shown in FIG. 6.

The above description is intended to be illustrative, and not restrictive. For example, the above-described examples (or one or more aspects thereof) may be used in combination with each other. Other implementations can be used, such as by one of ordinary skill in the art upon reviewing the above description. Also, various features may be grouped together and less than all features of a particular disclosed implementation may be used. Thus, the following aspects are hereby incorporated into the above description as examples or implementations, with each aspect standing on its own as a separate implementation, and it is contemplated that such implementations can be combined with each other in various combinations or permutations. Therefore, the spirit and scope of the appended claims should not be limited to the foregoing description.

What is claimed is:

1. A method of optical measurement of a sample, the method comprising:
obtaining metrology data from a location on the sample, wherein the metrology data is a combination of a first base contribution from a structure-of-interest (SOI) having known parameters, a second base contribution from a section having unknown structure, and a deviation contribution from the section having unknown structure;
obtaining an influence map for the sample comprising the deviation contribution associated with a plurality of locations on the sample;
removing from the metrology data obtained from the location the deviation contribution associated with the location to generate processed metrology data comprising the combination of the first base contribution from the SOI and the second base contribution from the section having unknown structure without the deviation contribution; and
determining one or more parameters of the SOI using the processed metrology data and a model for optical measurement of the SOI comprising a rigorous model that represents the SOI and an effective model that represents the second base contribution from the section having unknown structure without the deviation contribution.

2. The method of claim 1, wherein the plurality of locations on the sample in the influence map are within a region-of-interest (ROI) and wherein the deviation contribution from the section having unknown structure varies across the ROI.

3. The method of claim 2, wherein the ROI is within a die on a wafer.

4. The method of claim 2, wherein the ROI consists of one or more measurement sites from a plurality of dies across a wafer.

5. The method of claim 1, wherein the section having unknown structure resides at a region that underlies the SOI, is on top of the SOI, or is besides the SOI.

6. The method of claim 1, wherein the metrology data comprises at least one of ellipsometric data, reflectometric data, interferometric data, Fourier-Transform Infrared Spectroscopy (FTIR) data, or a combination thereof.

7. A metrology device configured for optical measurement of a sample, comprising:
a light source that produces light to be incident on the sample;
a detector that detects the light from the sample;
means for obtaining metrology data from a location on the sample, wherein the metrology data is a combination of a first base contribution from a structure-of-interest (SOI) having known parameters, a second base contribution from a section having unknown structure, and a deviation contribution from the section having unknown structure;
means for obtaining an influence map for the sample comprising the deviation contribution associated with a plurality of locations on the sample;
means for removing from the metrology data obtained from the location the deviation contribution associated with the location to generate processed metrology data comprising the combination of the first base contribution from the SOI and the second base contribution from the section having unknown structure without the deviation contribution; and
means for determining one or more parameters of the SOI using the processed metrology data and a model for optical measurement of the SOI comprising a rigorous model that represents the SOI and an effective model that represents the second base contribution from the section having unknown structure without the deviation contribution.

8. The metrology device of claim 7, wherein the plurality of locations on the sample in the influence map are within a region-of-interest (ROI) and wherein the deviation contribution from the section having unknown structure varies across the ROI.

9. The metrology device of claim 8, wherein the ROI is within a die on a wafer.

10. The metrology device of claim 8, wherein the ROI consists of one or more measurement sites from a plurality of dies across a wafer.

11. The metrology device of claim 7, wherein the section having unknown structure resides at a region that underlies the SOI, is on top of the SOI, or is besides the SOI.

12. The metrology device of claim 7, wherein the metrology data comprises at least one of ellipsometric data, reflectometric data, interferometric data, Fourier-Transform Infrared Spectroscopy (FTIR) data, or a combination thereof.

13. A method of producing an influence map for optical measurement of a sample, the method comprising:
obtaining metrology data from a plurality of locations, wherein the metrology data obtained from each location is a combination of a first base contribution from a structure-of-interest (SOI) having known structure, a second base contribution from a section having unknown structure, and a deviation contribution from the section having unknown structure;
determining for each location the deviation contribution from the section having unknown structure based on the metrology data from the plurality of locations; and
storing the deviation contribution and associated location for each location of the plurality of locations to generate the influence map of the section having unknown structure.

14. The method of claim 13, wherein determining for each location the deviation contribution from the section having unknown structure based on the metrology data from the plurality of locations comprises decoupling the deviation contribution from a combination of the first base contribution and the second base contribution using at least one of Principal Component Analysis (PCA), Independent Component Analysis (ICA), Partial Least Squares (PLS), or a combination thereof with the metrology data obtained from the plurality of locations.

15. The method of claim 13, wherein the plurality of locations are within a region-of-interest (ROI) and wherein the deviation contribution from the section having unknown structure varies across the ROI.

16. The method of claim 15, wherein the ROI is within a die on a wafer.

17. The method of claim 15, wherein the ROI consists of one or more measurement sites from a plurality of dies across a wafer.

18. The method of claim 13, wherein the section having unknown structure resides at a region that underlies the SOI, is on top of the SOI, or is besides the SOI.

19. The method of claim 13, wherein the metrology data comprises at least one of ellipsometric data, reflectometric data, interferometric data, Fourier-Transform Infrared Spectroscopy (FTIR) data, or a combination thereof.

20. The method of claim 13, wherein the plurality of locations are in a plurality of regions-of-interest (ROIs), the method further comprising:
determining an influence map for each ROI; and
combining the influence map for each ROI.

21. The method of claim 20, wherein the plurality of ROIs is located over at least a same wafer, multiple wafers, or a combination thereof.

22. The method of claim 13, wherein the plurality of locations are in a plurality of region-of-interest (ROIs), the method further comprising:
determining an influence map for each ROI; and
saving the influence maps for the plurality of ROIs to a library or look-up table.

23. The method of claim 13, wherein the plurality of locations are in a ROI within a die, the method further comprising:
determining an influence map for each location in the plurality of locations in the ROI; and
stitching together influence maps for the plurality of locations.

24. A system for producing an influence map for optical measurement of a sample, comprising:
means for obtaining metrology data from a plurality of locations, wherein the metrology data obtained from each location is a combination of a first base contribution from a structure-of-interest (SOI) having known structure, a second base contribution from a section having unknown structure, and a deviation contribution from the section having unknown structure;
means for determining for each location the deviation contribution from the section having unknown structure based on the metrology data from the plurality of locations; and
means for storing in the memory the deviation contribution and associated location for each location of the plurality of locations to generate the influence map of the section having unknown structure.

25. The system of claim 24, wherein the means for determining for each location the deviation contribution from the section having unknown structure based on the metrology data from the plurality of locations comprises a means for decoupling the deviation contribution from a combination of the first base contribution and the second base contribution using at least one of Principal Component Analysis (PCA), Independent Component Analysis (ICA), Partial Least Squares (PLS), or a combination thereof with the metrology data obtained from the plurality of locations.

26. The system of claim 24, wherein the plurality of locations are within a region-of-interest (ROI) and wherein the deviation contribution from the section having unknown structure varies across the ROI.

27. The system of claim 26, wherein the ROI is within a die on a wafer.

28. The system of claim 26, wherein the ROI consists of one or more measurement sites from a plurality of dies across a wafer.

29. The system of claim 24, wherein the section having unknown structure resides at a region that underlies the SOI, is on top of the SOI, or is besides the SOI.

30. The system of claim 24, wherein the metrology data comprises at least one of ellipsometric data, reflectometric data, interferometric data, Fourier-Transform Infrared Spectroscopy (FTIR) data, or a combination thereof.

31. The system of claim 24, wherein the plurality of locations are in a plurality of regions-of-interest (ROIs), wherein the system further comprises:
means for determining an influence map for each ROI; and
means for combining the influence map for each ROI.

32. The system of claim 31, wherein the plurality of ROIs is located over at least a same wafer, multiple wafers, or a combination thereof.

33. The system of claim 24, wherein the plurality of locations are in a plurality of region-of-interest (ROIs), wherein the system further comprises:
means for determining an influence map for each ROI; and
means for saving the influence maps for the plurality of ROIs to a library or look-up table.

34. The system of claim 24, wherein the plurality of locations are in a ROI within a die, wherein execution of the instructions causes the system to perform operations further comprising:
means for determining an influence map for each location in the plurality of locations in the ROI; and
means for stitching together influence maps for the plurality of locations.

35. A method of producing a model for optical measurement of a structure-of-interest (SOI) on a sample, the method comprising:
obtaining metrology data from different locations on the sample, wherein each of the different locations on the sample comprises the SOI having known structure and a section having unknown structure that varies over the different locations, wherein metrology data obtained from each of the different locations comprise a first base contribution from the SOI having known structure, a second base contribution from the section having unknown structure, and a deviation contribution from the section having unknown structure, wherein the deviation contribution from the section having unknown structure varies for each of the different locations;
obtaining an influence map for the sample comprising deviation contributions associated with each of the different locations; and
generating the model for optical measurement of the SOI using the metrology data obtained from the different locations and the influence map, the model comprising a rigorous model that represents the SOI and an effective model that represents the second base contribution from the section having unknown structure without the deviation contribution.

36. The method of claim 35, wherein generating the model for optical measurement of the SOI comprises:
removing the deviation contribution from the metrology data obtained from each of different locations to generate processed metrology data comprising a combination of the first base contribution from the SOI and the second base contribution from the section having unknown structure without the deviation contribution; and
developing the model based on the processed metrology data.

37. The method of claim 35, wherein the different locations are within a region-of-interest (ROI) and wherein the deviation contribution from the section having unknown structure varies across the ROI.

38. The method of claim 37, wherein the ROI is within a die on a wafer.

39. The method of claim 37, wherein the ROI consists of one or more measurement sites from a plurality of dies across a wafer.

40. The method of claim 35, wherein the section having unknown structure resides at a region that underlies the SOI, is on top of the SOI, or is besides the SOI.

41. The method of claim 35, wherein the metrology data comprises at least one of ellipsometric data, reflectometric data, interferometric data, Fourier-Transform Infrared Spectroscopy (FTIR) data, or a combination thereof.

42. A system for producing a model for optical measurement of a structure-of-interest (SOI) on a sample, comprising:
means for obtaining metrology data from different locations on the sample, wherein each of the different locations on the sample comprises the SOI having known structure and a section having unknown structure that varies over the different locations, wherein metrology data obtained from each of the different locations comprise a first base contribution from the SOI having the known structure, a second base contribution from the section having unknown structure, and a deviation contribution from the section having unknown structure, wherein the deviation contribution from the section having unknown structure varies for each of the different locations;
means for obtaining an influence map for the sample comprising deviation contributions associated with each of the different locations; and
means for generating the model for optical measurement of the SOI using the metrology data obtained from the different locations and the influence map, the model comprising a rigorous model that represents the SOI and an effective model that represents the second base contribution from the section having unknown structure without the deviation contribution.

43. The system of claim 42, wherein the means for generating the model for optical measurement of the SOI comprises:
means for removing the deviation contribution from the metrology data obtained from each of different locations to generate processed metrology data comprising a combination of the first base contribution from the SOI and the second base contribution from the section having unknown structure without the deviation contribution; and
means for developing the model based on the processed metrology data.

44. The system of claim 42, wherein the different locations are within a region-of-interest (ROI) and wherein the deviation contribution from the section having unknown structure varies across the ROI.

45. The system of claim 44, wherein the ROI is within a die on a wafer.

46. The system of claim 44, wherein the ROI consists of one or more measurement sites from a plurality of dies across a wafer.

47. The system of claim 42, wherein the section having unknown structure resides at a region that underlies the SOL, is on top of the SOL, or is besides the SOL.

48. The system of claim 42, wherein the metrology data comprises at least one of ellipsometric data, reflectometric data, interferometric data, Fourier-Transform Infrared Spectroscopy (FTIR) data, or a combination thereof.
